(19) United States
(12) Patent Application Publication
(10) Pub. No.: US 2025/0351693 A1
(43) Pub. Date: Nov. 13, 2025

(54) DISPLAY DEVICE

(71) Applicant: Samsung Display Co., LTD., Yongin-si (KR)

(72) Inventors: Kye Uk LEE, Yongin-si (KR); Sun Kwang KIM, Yongin-si (KR); Si Hyun AHN, Yongin-si (KR)

(73) Assignee: Samsung Display Co., LTD., Yongin-si (KR)

(21) Appl. No.: 19/022,446

(22) Filed: Jan. 15, 2025

(30) Foreign Application Priority Data
May 7, 2024 (KR) 10-2024-0059889

(51) Int. Cl. H10K 59/131; H10K 59/122; H10K 59/126

(52) U.S. Cl. CPC H10K 59/131; H10K 59/122; H10K 59/126

(57) ABSTRACT

The disclosure relates to a display device, and, to a display device and an electronic device capable of repairing data lines. A display device includes a data line disposed on a substrate; a passivation layer disposed on the data line; a via layer disposed on the passivation layer; a shielding line disposed on the via layer and overlapping the data line; a light-emitting element layer disposed on the shielding line; a first hole penetrating the via layer and overlapping a side of the data line; and a second hole penetrating the via layer and overlapping another side of the data line.

### CROSS-REFERENCE TO RELATED APPLICATION(S)

This application claims priority to and benefits of Korean Patent Application No. 10-2024-0059889 under 35 U.S.C. § 119 filed on May 7, 2024 in the Korean Intellectual Property Office, the entire contents of which are incorporated herein by reference.

### BACKGROUND

### 1. Technical Field

The disclosure relates to a display device, and to a display device and an electronic device capable of repairing data lines.

### 2. Description of the Related Art

An organic light emitting diode (OLED) display has self-emitting characteristics and, unlike a liquid crystal display (LCD), does not require a separate light source, allowing for reduced thickness and weight. The OLED display exhibits high-quality characteristics such as low power consumption, high brightness, and high response speed and has thus been recognized as a next-generation display device for TVs, monitors, and portable electronic devices.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Aspects of the disclosure provide a display device capable of repairing data lines.

However, aspects of the disclosure are not restricted to those set forth herein. The above and other aspects of the disclosure will become more apparent to one of ordinary skill in the art to which the disclosure pertains by referencing the detailed description of the disclosure given below.

According to an aspect of the disclosure, a display device may include a data line disposed on a substrate; a passivation layer disposed on the data line; a via layer disposed on the passivation layer; a shielding line disposed on the via layer and overlapping the data line; a light-emitting element layer disposed on the shielding line; a first hole penetrating the via layer and overlapping a side of the data line; and a second hole penetrating the via layer and overlapping another side of the data line.

The shielding line may receive a direct current (DC) power.

The shielding line may be disposed in the first hole and the second hole.

The light-emitting element layer may include an anode electrode and a pixel-defining layer disposed on the anode electrode, and the first hole and the second hole may not overlap the anode electrode.

The first hole and the second hole may overlap the pixel-defining layer.

The data line may include a first sub-data line and a second sub-data line that are separated from each other, and facing ends of the first sub-data line and the second sub-data line may be disposed between the first hole and the second hole in a plan view.

The shielding line may include a repair electrode, a first sub-shielding line, and a second sub-shielding line that are separated from each other.

The repair electrode may overlap facing ends of the first sub-data line and the second sub-data line.

The first hole may be disposed between an end of the repair electrode facing the first sub-shielding line and an end of the first sub-data line facing the second sub-data line, and the second hole may be disposed between another end of the repair electrode facing the second sub-shielding line and an end of the second sub-data line facing the first sub-data line.

Each of the first hole and the second hole may further penetrate the passivation layer.

A side of the repair electrode may be connected to the first sub-data line through the first hole, and another side of the repair electrode may be connected to the second sub-data line through the second hole.

The repair electrode may receive a data voltage from the data line, and each of the first sub-shielding line and the second sub-shielding line may receive a DC power.

According to an aspect of the disclosure, a display device may include a data line disposed on a substrate; a passivation layer disposed on the data line; a via layer disposed on the passivation layer; a shielding line disposed on the via layer and overlapping the data line; a light-emitting element layer disposed on the shielding line; a first hole penetrating the via layer and disposed between a side of the data line and the shielding line; and a second hole penetrating the via layer and disposed between another side of the data line and the shielding line.

The shielding line may receive a direct current (DC) power.

The shielding line may be disposed in the first hole and the second hole.

The light-emitting element layer may include an anode electrode and a pixel-defining layer disposed on the anode electrode, and the first hole and the second hole do not overlap the anode electrode.

The first hole and the second hole may overlap the pixel-defining layer.

The data line may include a first sub-data line and a second sub-data line that are separated from each other, and facing ends of the first sub-data line and the second sub-data line are disposed between the first hole and the second hole in a plan view.

The shielding line may include a repair electrode, a first sub-shielding line, and a second sub-shielding line that are separated from one another.

The repair electrode may overlap facing ends of the first sub-data line and the second sub-data line.

The first hole may be disposed between an end of the repair electrode facing the first sub-shielding line and an end of the first sub-data line facing the second sub-data line in a plan view, and the second hole is disposed between another end of the repair electrode facing the second sub-shielding line and an end of the second sub-data line facing the first sub-data line in a plan view.

Each of the first hole and the second hole may further penetrate the passivation layer.

A side of the repair electrode may be connected to the first sub-data line through the first hole, and another side of the repair electrode is connected to the second sub-data line through the second hole.

The repair electrode may receive a data voltage from the data line, and each of the first sub-shielding line and the second sub-shielding line receives a DC power.

According to an aspect of the disclosure, an electronic device comprising a display device, wherein the display device may include a data line disposed on a substrate; a passivation layer disposed on the data line; a via layer disposed on the passivation layer; a shielding line disposed on the via layer and overlapping the data line; a light-emitting element layer disposed on the shielding line; a first hole penetrating the via layer and overlapping a side of the data line; and a second hole penetrating the via layer and overlapping another side of the data line.

According to the aforementioned and other embodiments of the disclosure, data lines can be repaired.

It should be noted that the effects of the disclosure are not limited to those described above, and other effects of the disclosure will be apparent from the following description.

### BRIEF DESCRIPTION OF THE DRAWINGS

The above and other aspects and features of the disclosure will become more apparent by describing in detail embodiments thereof with reference to the attached drawings, in which:

FIG. 1 is a schematic plan view illustrating a display device according to an embodiment;

FIG. 2 is a schematic plan view illustrating a display panel of FIG. 1;

FIG. 3 is a schematic diagram of an equivalent circuit illustrating a pixel according to an embodiment;

FIG. 4 is a diagram illustrating an array of a display device according to an embodiment;

FIG. 5 is a schematic cross-sectional view taken along line XI-XI′ of FIG. 4;

FIG. 6 is a diagram illustrating the array of a display device according to an embodiment;

FIG. 7 is a schematic cross-sectional view taken along line XII-XII′ of FIG. 6;

FIGS. 8 through 13 are schematic cross-sectional views for explaining a method of manufacturing a display device according to an embodiment;

FIG. 14 is a block diagram of an electronic device according to an embodiment; and

FIGS. 15, 16 and 17 are schematic diagrams of electronic devices according to various embodiments.

### DETAILED DESCRIPTION OF THE EMBODIMENTS

Advantages and features of the disclosure and methods to achieve them will become apparent from the descriptions of embodiments hereinbelow with reference to the accompanying drawings. However, the disclosure is not limited to embodiments disclosed herein but may be implemented in various different ways. The embodiments are provided for making the disclosure thorough and for fully conveying the scope of the disclosure to those skilled in the art. It is to be noted that the scope of the disclosure is also defined by the claims.

As used herein, a phrase “an element A on an element B” refers to that the element A may be disposed directly on the element B and/or the element A may be disposed indirectly on the element B via another element C. Like reference numerals denote like elements throughout the descriptions. The figures, dimensions, ratios, angles, numbers of elements given in the drawings are illustrative and are not limiting.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

Although terms such as first, second, etc. are used to distinguish arbitrarily between the elements such terms describe, and thus these terms are not necessarily intended to indicate temporal or other prioritization of such elements. These terms are used to distinguish one element from another. Accordingly, as used herein, a first element may be a second element within the technical scope of the disclosure.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “comprises,” “comprising,” “includes,” and/or “including,” “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be understood that when an element (or a region, a layer, a portion, or the like) is referred to as “being on”, “connected to” or “coupled to” another element in the specification, it can be directly disposed on, connected or coupled to another element mentioned above, or intervening elements may be disposed therebetween.

It will be understood that the terms “connected to” or “coupled to” may include a physical or electrical connection or coupling.

Features of various embodiments may be combined partially or totally. As will be clearly appreciated by those skilled in the art, technically various interactions and operations are possible. Various embodiments can be practiced individually or in combination.

Hereinafter, embodiments will be described with reference to the accompanying drawings.

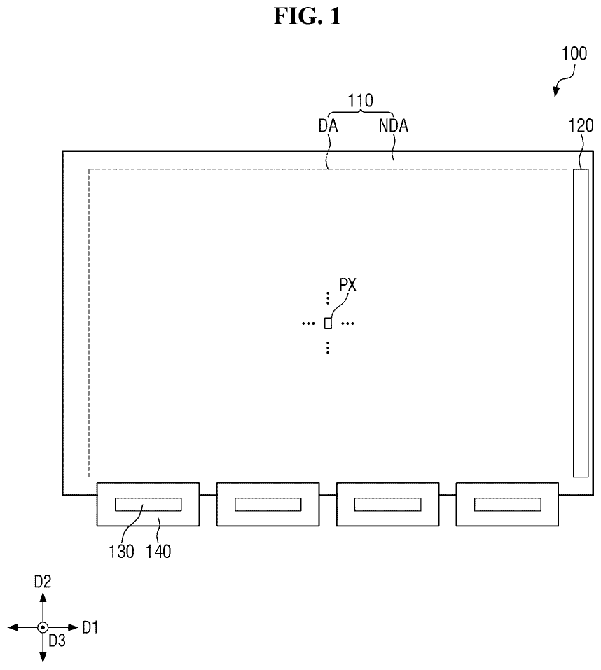

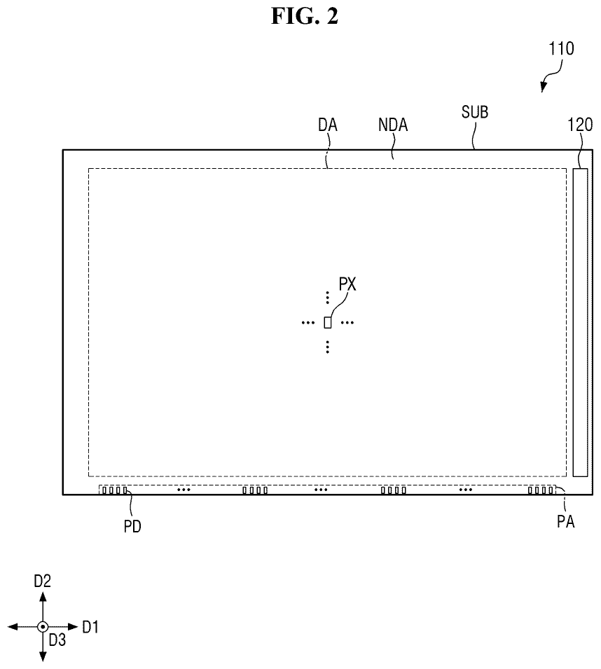

FIG. 1 is a schematic plan view illustrating a display device 100 according to an embodiment. FIG. 2 is a schematic plan view illustrating a display panel 110 of FIG. 1.

Referring to FIGS. 1 and 2, the display device 100, which is a device for displaying videos or still images, may be used as the display screen of various products such as mobile phones, smart phones, tablet personal computers (PCs), smart watches, watch phones, mobile communication terminals, electronic notebooks, e-book readers, portable multimedia players (PMPs), navigation devices, ultra-mobile PCs (UMPCs), as well as televisions (TVs), laptops, monitors, billboards, and Internet of Things (IoT) devices. These are presented as examples, and the display device 100 may also be employed in other electronic devices.

In an embodiment, the display device 100 may be a light-emitting display device such as an organic light-emitting display device including organic light-emitting diodes (OLEDs), a quantum dot light-emitting display device including a quantum dot light-emitting layer, an inorganic light-emitting display device including an inorganic semiconductor, or an ultra-small light-emitting display device including ultra-small light-emitting diodes (LEDs) such as micro- or nano-LEDs, but the disclosure is not limited thereto. By way of example, the display device 100 may be another type of display device other than a light-emitting display device. Embodiments where the display device 100 is a light-emitting display device (for example, an organic light-emitting display device) will hereinafter be disclosed.

The display device 100 may include a display panel 110, which may include pixels PX, and first and second driving units 120 and 130, which supply driving signals to the pixels PX. The display device 100 may include additional features. For example, the display device 100 may further include a power supply unit for supplying power supply voltages to the pixels PX, the first driving unit 120, and the second driving unit 130, and a timing controller for controlling the operation of the first and second driving units 120 and 130.

The display panel 110 may include a display area DA and a non-display area NDA. The display area DA may be an area that displays an image by including the pixels PX. For example, the display area DA may include pixel areas where the respective pixels PX are disposed. The non-display area NDA is the remaining area excluding the display area DA, and no image may be displayed in the non-display area NDA. In an embodiment, the non-display area NDA may be located or disposed around the display area DA and may surround the display area DA or may be adjacent to the display area DA.

FIGS. 1 and 2 define a first direction D1, a second direction D2, and a third direction D3. In an embodiment, the first direction D1 may be the horizontal direction of the display panel 110, the second direction D2 may be the vertical direction of the display panel 110, and the third direction D3 may be the thickness direction of the display panel 110.

In an embodiment, the display panel 110 may be rectangular in shape on a plane. FIGS. 1 and 2 illustrate a display panel 110 with a longer horizontal length than its vertical length, but the shape of the display panel 110 is not particularly limited. For example, the display panel 110 may have a longer vertical length than its horizontal length, or it may be square-shaped, etc. The display panel 110 may include angular corners or rounded corners.

The planar shape of the display panel 110 is not limited to the illustrated rectangular shape and may be applied in various other shapes. For example, the display panel 110 may have another polygonal shape that is non-rectangular, a circular shape, an elliptical shape, or an irregular shape.

In an embodiment, the display panel 110 may be substantially flat on a plane defined by the first and second directions D1 and D2 and may have a uniform thickness in the third direction D3. By way of example, the display panel 110 may be provided in a three-dimensional (3D) shape having curved surfaces.

The display panel 110 may be provided as a rigid panel that is substantially non-deformable, or may be provided as a flexible panel that can be deformed in at least one part, such as being foldable, bendable, or rollable. The display panel 110 may be provided in the display device 100 in a non-bent state or in a bent state in some sections.

The display panel 110 may include a substrate SUB and pixels PX disposed on the substrate SUB. The pixels PX may be arranged or disposed in the display area DA on the substrate SUB.

The substrate SUB, which is a base member for manufacturing or providing the display panel 110, may form the base surface of the display panel 110. The substrate SUB may include the display area DA and the non-display area NDA around the display area DA.

The display area DA may have various shapes. For example, the display area DA may have a rectangular shape, a non-rectangular polygonal shape, a circular shape, an elliptical shape, an irregular shape, or another shape. In an embodiment, the display area DA may have a shape corresponding to the shape of the display panel 110.

In the display area DA, the pixels PX may be provided and/or arranged or disposed. For example, the display area DA may include pixel regions where the individual pixels PX are arranged or disposed.

In an embodiment, the display device 100 may be a light-emitting display device, and each of the pixels PX may include a light-emitting element located or disposed in each emission area and a pixel circuit connected to the light-emitting element. The term “connected,” as used herein, may encompass both electrical and/or physical connections. Each pixel circuit may include transistors (for example, transistors including at least one switching transistor and a driving transistor generating a driving current corresponding to a data signal) and at least one capacitor (for example, a storage capacitor).

The non-display area NDA may include a pad area PA where pads PD are disposed. In an embodiment, the non-display area NDA may further include a driving circuit area located or disposed on at least a side of the display area DA. In the non-display area NDA, at least one driving unit, the pads PD, and/or wiring may be disposed.

In the driving circuit area, at least one driving unit or a part of the driving unit for driving the pixels PX may be disposed. For example, in the driving circuit area on the substrate SUB, circuit elements constituting the first driving unit 120 (for example, driving transistors and driving capacitors constituting the stage circuits of the first driving unit 120) may be disposed. In an embodiment, the circuit elements of the first driving unit 120 may be formed in the display panel 110 along with the pixels PX. In an embodiment, the driving transistors provided in the first driving unit 120 may be of substantially the same type and/or structure as (or a similar type and/or structure to) the transistors provided to the pixels PX, and may be formed simultaneously with the transistors of the pixels PX.

The pads PD may be arranged or disposed in the pad area PA. At least one circuit board 140 may be arranged or disposed and/or bonded on the pad area PA. In an embodiment, circuit boards 140 connected to different pads PD may be disposed in the pad area PA. The pads PD may include signal pads and power pads for transmitting driving signals and power supply voltages for driving the pixels PX and/or the first driving unit 120 to the inside of the display panel 110.

The first and second driving units 120 and 130 may generate driving signals for controlling the operation timing and brightness of the pixels PX, and may supply the driving signals to the pixels PX. For example, the first driving unit 120 may be a gate driving unit including a scan driver and may be connected to the pixels PX through respective gate lines. The first driving unit 120 may supply gate signals (for example, scan signals and/or control signals for controlling the driving timing of the pixels PX, including emission control signals) to the pixels PX. The second driving unit 130 may be a data driving unit including source driving circuits and may be connected to the pixels PX through respective data lines. The second driving unit 130 may supply data signals to the pixels PX.

In an embodiment, at least one of the first and second driving units 120 and 130, or parts of the first and second driving units 120 and 130, may be embedded in the display panel 110. For example, the first driving unit 120 or a part of the first driving unit 120 may be disposed on the substrate SUB of the display panel 110 and may be disposed and/or formed in the non-display area NDA.

In FIG. 1, the first driving unit 120 is illustrated as being formed on one side or a side of the display area DA (for example, in a part of the non-display area NDA on the right side of the display area DA), but the disclosure is not limited thereto. One of the first and second driving units 120 and 130, for example, the first driving unit 120, may be located or disposed on another side of the display area DA (for example, in a part of the non-display area NDA on the left side of the display area DA), or may be located or disposed on both sides of the display area DA (for example, in parts of the non-display area NDA on both the left and right sides of the display area DA). By way of example, a part of the first driving unit 120 may be located or disposed in the non-display area NDA, and another part of the first driving unit 120 may be located or disposed in a non-emission area in the display area DA (for example, the area between the emission areas of the pixels PX).

In an embodiment, the other driving unit, or a part thereof, may be disposed or formed outside the display panel 110 and electrically connected to the display panel 110. For example, the second driving unit 130 may be implemented with integrated circuit (IC) chips and disposed on circuit boards 140 electrically connected to the pixels PX of the display panel 110. The second driving unit 130 may be implemented as at least one IC chip and mounted in the non-display area NDA of the display panel 110.

The circuit boards 140 may be connected to the display panel 110 through the pads PD. In an embodiment, the circuit boards 140 may be flexible films such as flexible printed circuit boards (FPCBs), printed circuit boards (PCBs), or chip-on-films (COFs), but the disclosure is not limited thereto. In an embodiment, the circuit boards 140 may be connected to the timing controller and/or the power supply unit through circuit boards or connectors, etc.

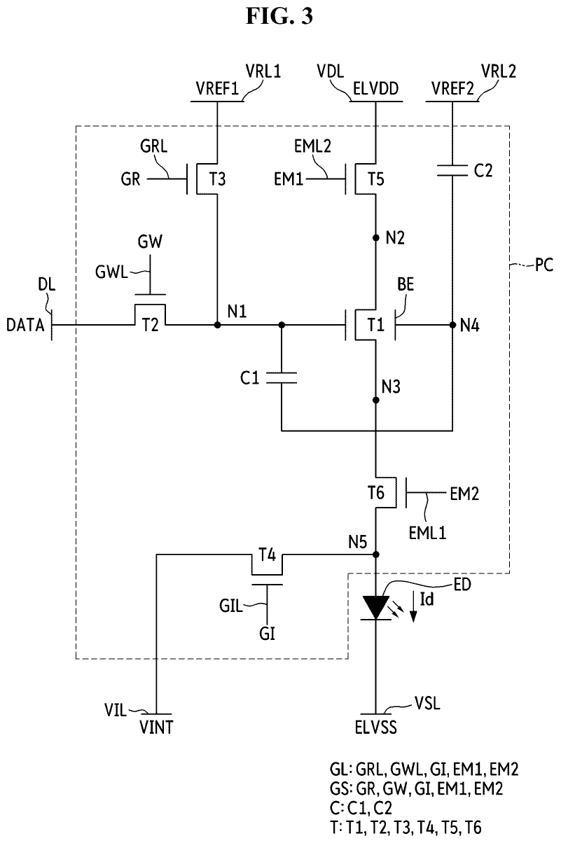

FIG. 3 is a schematic diagram of an equivalent circuit illustrating a pixel PX according to an embodiment. For example, FIG. 3 illustrates a pixel PX of the display device 100 that includes a light-emitting element ED. However, the type and/or structure of the pixel PX included in the display device 100 is not particularly limited and may vary.

Referring to FIGS. 1, 2, and 3, a pixel PX may include a light-emitting element ED and a pixel circuit PC connected to the light-emitting element ED. The light-emitting element ED, which is the light source of the pixel PX, may be an OLED, but the disclosure is not limited thereto. The pixel circuit PC may control the emission timing and brightness of the light-emitting element ED.

The pixel circuit PC may include transistors T and at least one capacitor C. For example, the pixel circuit PC may include first through fifth transistors T1 through T5, a first capacitor C1, and a second capacitor C2. FIG. 3 depicts an embodiment where all the first through sixth transistors T1 through T6 are N-type transistors, but the types of the transistors T are not limited thereto. For example, at least one of the transistors T may be formed as a P-type transistor.

The pixel circuit PC may supply a driving current Id to the light-emitting element ED in response to driving signals supplied from the first and second driving units 120 and 130. For example, the pixel circuit PC may supply the driving current Id to the light-emitting element ED in response to each gate signal GS supplied from the first driving unit 120 through a corresponding gate line GL and each data signal DATA supplied from the second driving unit 130 through a corresponding data line DL.

The first transistor T1 may be the driving transistor of the pixel PX, where the magnitude of a drain-source current (for example, the driving current Id) is determined by a gate-source voltage. The second through sixth transistors T2 through T6 may be switching transistors that turn on or off according to their respective gate-source voltages. Depending on the type (for example, P-type or N-type) and/or operating conditions of each of the first through sixth transistors T1 through T6, the first electrode of each of the first through sixth transistors T1 through T6 may be a drain electrode (or region) or a source electrode (or source region), while the second electrode of each of the first through sixth transistors T1 through T6 may be a different type of electrode from the first electrode of each of the first through sixth transistors T1 through T6. For example, if the first electrode of each of the first through sixth transistors T1 through T6 is a drain electrode, the second electrode of each of the first through sixth transistors T1 through T6 may be a source electrode.

The pixel PX may be connected to a first gate line GWL that transmits a first gate signal GW (for example, a scan signal), a second gate line GIL that transmits a second gate signal GI, a third gate line GRL that transmits a third gate signal GR, a fourth gate line EBL that transmits a fourth gate signal EMB, emission control lines EML that transmit emission control signals EM, and a data line DL that transmits a data signal DATA. The pixel PX may be connected to a first driving power supply line VDL that transmits a first pixel voltage ELVDD (also referred to as “first pixel power voltage”) and a second driving power supply line VSL that transmits a second pixel voltage ELVSS (also referred to as “second pixel power voltage”). In an embodiment, the pixel PX may be further connected to an initialization power supply line VIL that transmits an initialization voltage VINT (also referred to as “third pixel power voltage”), a first reference power supply line VRL1 that transmits a first reference voltage VREF1 (also referred to as “fourth pixel power voltage”), and a second reference power supply line VRL2 that transmits a second reference voltage VREF2 (also referred to as “fifth pixel power voltage”).

In an embodiment, the first through sixth transistors T1 through T6 may be oxide transistors, which include an oxide semiconductor (for example, oxide semiconductor material) and may also be referred to as “oxide semiconductor transistors.” For example, the active layer of each of the first through sixth transistors T1 through T6 may include an oxide semiconductor, but the disclosure is not limited thereto. For example, at least one of the transistors T may be formed of a semiconductor material other than an oxide semiconductor (for example, amorphous silicon or polysilicon).

Since the oxide semiconductor has high carrier mobility and low leakage current, significant voltage drops may not occur even in case that the driving time of an oxide transistor is extended. For example, in a case where the pixel PX may include an oxide transistor, changes in the brightness and/or color of an image that are caused by voltage drops may be minimal even in case that driven at low frequency, allowing for low-frequency driving. In case that the first through sixth transistors T1 through T6 are formed as oxide transistors, they can reduce or prevent leakage current in the pixel PX and reduce power consumption.

The oxide semiconductor may be sensitive to light, and external light may cause variations in the amount of current. In an embodiment, a light-shielding pattern or a light-shielding electrode (for example, a bottom electrode or a back-gate electrode) may be disposed below the active layer included in at least one transistor T to block external light. This can stabilize the operating characteristics of the at least one transistor T.

The first transistor T1 may include a gate electrode connected to a first node N1, a first electrode (for example, first drain electrode) connected to a second node N2, and a second electrode (for example, first source electrode) connected to a third node N3. The first electrode of the first transistor T1 may be connected to the first driving power supply line VDL via the fifth transistor T5, and the second electrode of the first transistor T1 may be connected to the light-emitting element ED via the sixth transistor T6. The first transistor T1 may control the magnitude (for example, intensity) of the driving current Id flowing to the light-emitting element ED in response to the data signal DATA transmitted to the first node N1.

In an embodiment, the first transistor T1 may further include a bottom electrode BE (for example, a bottom-gate electrode or back-gate electrode of the first transistor T1) connected to a fourth node N4. By connecting the bottom electrode BE of the first transistor T1 to the fourth node N4, the first transistor T1 may be formed as a double-gate transistor (for example, a source-sync double-gate transistor), improving its operational characteristics.

The second transistor T2 may include a second gate electrode GE2 connected to the first gate line GWL, a first electrode (for example, second drain electrode) connected to the data line DL, and a second electrode (for example, second source electrode) connected to the first node N1. The second transistor T2 may be turned on by the first gate signal GW (for example, a gate-on voltage of the first gate signal GW) transmitted via the first gate line GWL, connecting the data line DL to the first node N1. Thus, the data signal DATA transmitted via the data line DL may be delivered to the first node N1.

The third transistor T3 may include a gate electrode connected to the third gate line GRL, a first electrode (for example, third source electrode) connected to the first reference power supply line VRL1, and a second electrode (for example, third drain electrode) connected to the first node N1. The third transistor T3 may be turned on by the third gate signal GR transmitted via the third gate line GRL, delivering the first reference voltage VREF1 transmitted via the first reference power supply line VRL1 to the first node N1.

The fourth transistor T4 may include a gate electrode connected to the second gate line GIL, a first electrode (for example, fourth drain electrode) connected to the fifth node N5, and a second electrode (for example, fourth source electrode) connected to the initialization power supply line VIL. The fourth transistor T4 may be turned on by the second gate signal GI transmitted via the second gate line GIL, delivering the initialization voltage VINT transmitted via the initialization power supply line VIL, to the fifth node N5.

The fifth transistor T5 may include a gate electrode connected to a first emission control line EML1, a first electrode (for example, fifth drain electrode) connected to the first driving power supply line VDL, and a second electrode (for example, fifth source electrode) connected to the second node N2 (or the first electrode of the first transistor T1). The fifth transistor T5 may be turned on by a first emission control signal EM1 (for example, a gate-on voltage of the first emission control signal EM1) transmitted via the first emission control line EML1, thereby controlling the emission timing of the pixel PX.

The sixth transistor T6 may include a gate electrode connected to a second emission control line EML2, a first electrode (for example, sixth drain electrode) connected to the third node N3 (or the second electrode of the first transistor T1), and a second electrode (for example, fifth source electrode) connected to the fifth node N5. The sixth transistor T6 may be turned on by a second emission control signal EM2 (for example, a gate-on voltage of the second emission control signal EM2) transmitted via the second emission control line EML2, thereby controlling the emission timing of the pixel PX.

The second through sixth transistors T2 through T6 may or may not include bottom electrodes. In an embodiment, at least one switching transistor among the second through sixth transistors T2 through T6 may include a bottom electrode, which may be connected to the gate electrode of the at least one switching transistor. Connecting the bottom electrode to the gate electrode of a switching transistor can improve the off characteristics and switching speed of the switching transistor, provide additional voltage tolerance, reduce leakage current, and enhance voltage stability. For example, by forming a switching transistor with a short channel oxide transistor in a double-gate structure such as a gate-sync structure, the operational characteristics of the switching transistor can be improved.

The first capacitor C1 may be connected between the first node N1 and the fourth node N4. As a storage capacitor of the pixel PX, the first capacitor C1 may store a voltage corresponding to the threshold voltage of the first transistor T1 and the data signal DATA (for example, data voltage).

The second capacitor C2 may be connected between the second reference power supply line VRL2 and the fourth node N4 (for example, the bottom electrode BE of the first transistor T1). In an embodiment, the capacitance of the second capacitor C2 may be smaller than that of the first capacitor C1.

The light-emitting element ED may be connected between the fifth node N5 and the second driving power supply line VSL. For example, the light-emitting element ED may include a first electrode (for example, anode electrode or pixel electrode) connected to the third node N3, a second electrode (for example, cathode electrode or common electrode) facing the first electrode and connected to the second driving power supply line VSL, and a light-emitting layer interposed between the first and second electrodes. In an embodiment, the first electrode of the light-emitting element ED may be an individual electrode provided for each pixel PX, and the second electrode of the light-emitting element ED may be a common electrode shared by pixels PX. The light-emitting element ED may emit light with a brightness corresponding to the driving current Id supplied from the pixel circuit PC during the period of supply of the driving current Id.

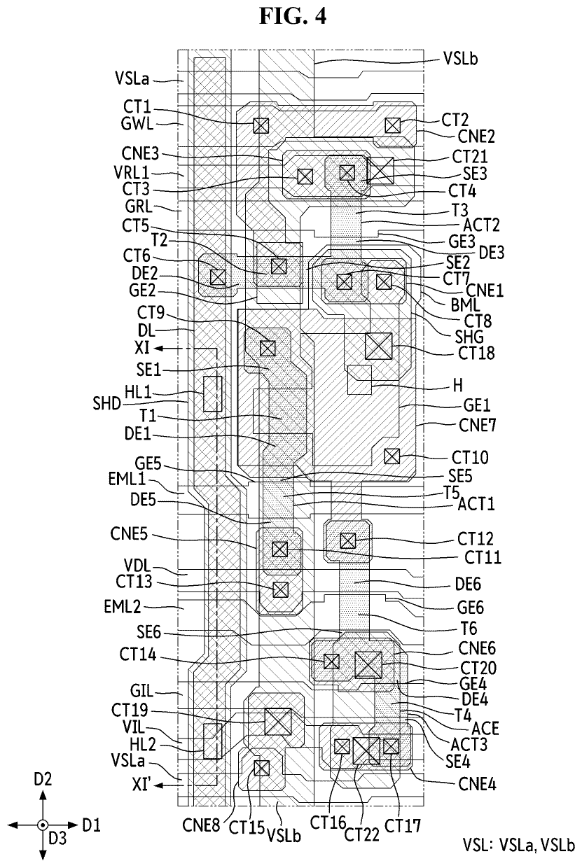

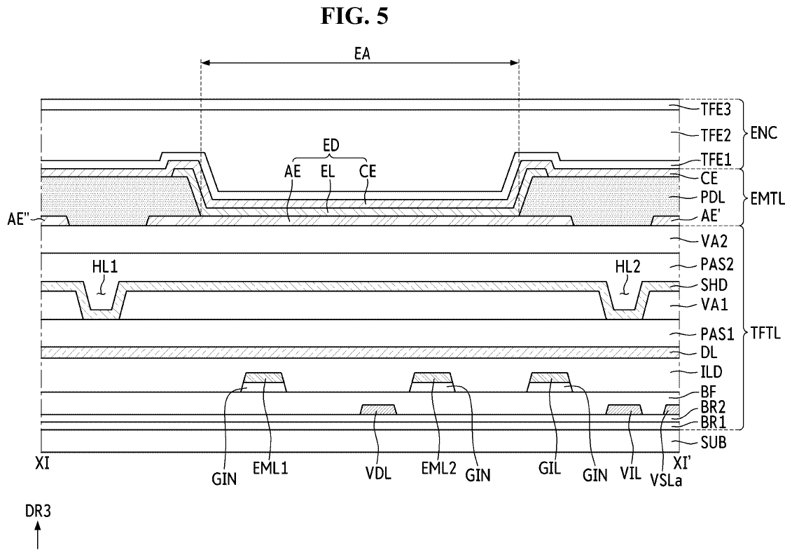

FIG. 4 is a diagram illustrating an array of a display device 100 according to an embodiment, FIG. 5 is a schematic cross-sectional view taken along the line X1-X1′ of FIG. 4. FIG. 4 illustrates, for example, an array for the pixel of FIG. 3.

Referring to FIG. 5, the display device 100 may include a substrate SUB, a thin-film transistor layer TFTL, a light-emitting element layer EMTL, and an encapsulation layer ENC. The thin-film transistor layer TFTL, the light-emitting element layer EMTL, and the encapsulation layer ENC may be sequentially arranged or disposed along the third direction D3 on the substrate SUB. Here, the thin-film transistor layer TFTL may include the first through sixth transistors T1 through T6, the first capacitor C1, and the second capacitor C2 of FIG. 3.

The substrate SUB may be a rigid substrate or a flexible substrate that is bendable, foldable, or rollable. The substrate SUB may be formed of an insulating material such as glass, quartz, or polymer resin. Examples of the polymer resin include polyethersulfone (PES), polyacrylate (PA), polyarylate (PAR), polyetherimide (PEI), polyethylene naphthalate (PEN), polyethylene terephthalate (PET), polyphenylene sulfide (PPS), polyallylate, polyimide (PI), polycarbonate (PC), cellulose triacetate (CAT), cellulose acetate propionate (CAP), and a combination thereof. By way of example, the substrate SUB may include a metallic material.

A first barrier layer BR1 may be disposed on the substrate SUB. For example, the first barrier layer BR1 may be disposed on the entire surface of the substrate SUB. The first barrier layer BR1 may protect the first through sixth transistors T1 through T6 of the thin-film transistor layer TFTL and a light-emitting layer EL of the light-emitting element layer EMTL from moisture penetrating through the substrate SUB, which is vulnerable to moisture. The first barrier layer BR1 may consist of inorganic films that may be alternately stacked each other. For example, the first barrier layer BR1 may be formed as a multilayer film in which one or more inorganic films among a silicon nitride layer, a silicon oxynitride layer, a silicon oxide layer, a titanium oxide layer, and an aluminum oxide layer may be alternately stacked each other.

A second barrier layer BR2 may be disposed on the first barrier layer BR1. The second barrier layer BR2 may have a same material and composition as the first barrier layer BR1.

The first gate line GWL, the first reference power supply line VRL1, a light-shielding layer, the first driving power supply line VDL, the initialization power supply line VIL, and the second driving power supply line VSL may be disposed on the second barrier layer BR2. The light-shielding layer may have a hole H overlapping a first gate electrode GE1 of the first transistor TR1. Conductive layers such as the first reference power supply line VRL1, the light-shielding layer, the first driving power supply line VDL, the initialization power supply line VIL, and the second driving power supply line VSL may be formed of a metallic material such as, for example, chromium (Cr) or molybdenum (Mo), or of black ink or black dye.

A buffer layer BF may be disposed on the light shielding layer. The buffer layer BF may protect the first through sixth transistors T1 through T6 of the thin-film transistor layer TFTL and the light-emitting layer EL of the light-emitting element layer EMTL from moisture penetrating through the substrate SUB, which is vulnerable to moisture. The buffer layer BF may consist of inorganic films that may be alternately stacked each other. For example, the buffer layer BF may be formed as a multilayer film in which one or more inorganic films among a silicon nitride layer, a silicon oxynitride layer, a silicon oxide layer, a titanium oxide layer, and an aluminum oxide layer may be alternately stacked each other.

A first active layer ACT1, a second active layer ACT2, and a third active layer ACT3 may be disposed on the buffer layer BF. The first active layer ACT1 may be an oxide-based active layer. For example, the first active layer ACT1 may be an oxide semiconductor including indium-gallium-zinc oxide (IGZO) or indium-gallium-zinc-tin oxide (IGZTO). The second active layer ACT2 may include a same material as the first active layer ACT1. For example, the second active layer ACT2 may be an active layer of an oxide substrate.

A gate insulating film GIN may be disposed on each of the first active layer ACT1, the second active layer ACT2, the third active layer ACT3, and the buffer layer BF. The gate insulating film GIN may include at least one of tetraethyl orthosilicate (TEOS), silicon nitride (SiNₓ), and silicon dioxide (SiO₂). For example, the gate insulating film GIN may have a dual-layer structure in which a silicon nitride film with a thickness of about 40 nm and a TEOS film with a thickness of about 80 nm may be sequentially stacked each other.

The first gate electrode GE1 of the first transistor T1, the second gate electrode GE2 of the second transistor T2, a third gate electrode GE3 of the third transistor T3, a fourth gate electrode GE4 of the fourth transistor T4, a fifth gate electrode GE5 of the fifth transistor T5, a sixth gate electrode GE6 of the sixth transistor T6, the third gate line GRL, the first emission control line EML1, the second emission control line EML2, and the second gate line GIL may be disposed on the gate insulating film GIN. For example, the first gate electrode GE1 may be disposed on the gate insulating film GIN to overlap the channel region of the first transistor T1 of the first active layer ACT1, the second gate electrode GE2 may be disposed on the gate insulating film GIN to overlap the channel region CH of the second transistor T2 of the second active layer ACT2, the third gate electrode GE3 may be disposed on the gate insulating film GIN to overlap the channel region CH of the second transistor T2 of the second active layer ACT2, the fourth gate electrode GE4 may be disposed on the gate insulating film GIN to overlap the channel region of the fourth transistor T4 of the third active layer ACT3, the fifth gate electrode GE5 may be disposed on the gate insulating film GIN to overlap the channel region of the fifth transistor T5 of the first active layer ACT1, and the sixth gate electrode may be disposed on the gate insulating film GIN to overlap the channel region of the sixth transistor T6 of the third active layer ACT3.

The first gate electrode GE1 may be connected to a lower light-shielding layer through both a contact hole penetrating the gate insulating film GIN and the hole H of the light-shielding layer. The lower light-shielding layer may be disposed below the light-shielding layer. A first drain electrode DE1 and a first source electrode SE1 may be formed on both sides of the first active layer ACT1 of the first gate electrode GE1, a second drain electrode DE2 and a second source electrode SE2 may be formed on both sides of the second gate electrode GE2 of the second active layer ACT2, a third drain electrode DE3 and a third source electrode SE3 may be formed on both sides of the third gate electrode GE3 of the second active layer ACT2, a fourth drain electrode DE4 and a fourth source electrode SE4 may be disposed on both sides of the fourth gate electrode GE4 of the third active layer ACT3, a fifth drain electrode DE5 and a fifth source electrode SE5 may be formed on both sides of the fifth gate electrode GE5 of the first active layer ACT1, and a sixth drain electrode DE6 and a sixth source electrode SE6 may be formed on both sides of the sixth gate electrode GE6 of the third active layer ACT3.

The third gate line GRL may be integral with the first gate electrode GE1.

The first emission control line EML1 may be integral with the fifth gate electrode GE5.

The second emission control line EML2 may be integral with the sixth gate electrode GE6.

The second gate line GIL may be integral with the fourth gate electrode GE4.

An interlayer insulating film ILD may be disposed on the first gate electrode GE1 of the first transistor T1, the second gate electrode GE2 of the second transistor T2, the third gate electrode GE3 of the third transistor T3, the fourth gate electrode GE4 of the fourth transistor T4, the fifth gate electrode GE5 of the fifth transistor T5, the sixth gate electrode GE6 of the sixth transistor T6, the third gate line GRL, the first emission control line EML1, the second emission control line EML2, and the second gate line GIL. The interlayer insulating film ILD may be formed as an inorganic film such as, for example, a silicon nitride layer, a silicon oxynitride layer, a silicon oxide layer, a titanium oxide layer, or an aluminum oxide layer. By way of example, the interlayer insulating film ILD may include inorganic films.

The data line DL, a first connection electrode CNE1, a second connection electrode CNE2, a third connection electrode CNE3, a fourth connection electrode CNE4, a fifth connection electrode CNE5, a sixth connection electrode CNE6, a seventh connection electrode CNE7, and an eighth connection electrode CNE8 may be disposed on the interlayer insulating film ILD. The data line DL may be connected to the second drain electrode DE2 of the second transistor T2 through a sixth contact hole CT6 penetrating the interlayer insulating film ILD.

One side or a side of the first connection electrode CNE1 may be connected to the first gate electrode GE1 through an eighth contact hole CT8 penetrating the interlayer insulating film ILD, and the other side or another side of the first connection electrode CNE1 may be connected to the second source electrode SE2 and the third drain electrode DE3 of the second active layer ACT2 through a seventh contact hole CT7 penetrating the interlayer insulating film ILD.

One side or a side of the second connection electrode CNE2 may be connected to the second gate electrode GE2 through a fifth contact hole CT5 penetrating the interlayer insulating film ILD, and the other side or another side of the second connection electrode CNE2 may be connected to the first gate line GWL through first and second contact holes CT1 and CT2 penetrating the interlayer insulating film ILD and the buffer layer BF.

One side or a side of the third connection electrode CNE3 may be connected to the third source electrode SE3 of the second active layer ACT2 through a fourth contact hole CT4 penetrating the interlayer insulating film ILD, and the other side or another side of the third connection electrode CNE3 may be connected to the first reference power supply line VRL1 through a third contact hole CT3 penetrating the interlayer insulating film ILD and the buffer layer BF.

One side or a side of the fourth connection electrode CNE4 may be connected to the fourth source electrode SE4 of the third active layer ACT3 through a seventeenth contact hole CT17 penetrating the interlayer insulating film ILD, and the other side or another side of the fourth connection electrode CNE4 may be connected to the initialization power supply line VIL through a sixteenth contact hole CT16 penetrating the interlayer insulating film ILD and the buffer layer BF.

One side or a side of the fifth connection electrode CNE5 may be connected to the fifth drain electrode DE5 through an eleventh contact hole CT11 penetrating the interlayer insulating film ILD, and the other side or another side of the fifth connection electrode CNE5 may be connected to the first driving power supply line VDL through a thirteenth contact hole CT13 penetrating the interlayer insulating film ILD and the buffer layer BF.

The sixth connection electrode CNE6 may be connected to the sixth source electrode DE5 through a fourteenth contact hole CT14 penetrating the interlayer insulating film ILD.

One side or a side of the seventh connection electrode CNE7 may be connected to the first source electrode SE1 through a ninth contact hole CT9 penetrating the interlayer insulating film ILD, another side of the seventh connection electrode CNE7 may be connected to the light-shielding layer BML through a tenth contact hole CT10 penetrating the interlayer insulating film ILD and the buffer layer BF, and yet another side of the seventh connection electrode CNE7 may be connected to the sixth drain electrode DE6 of the third active layer ACT3 through a twelfth contact hole CT12 penetrating the interlayer insulating film ILD.

The eighth connection electrode CNE8 may be connected to a first sub-driving power supply line VSLa through a fifteenth contact hole CT15 penetrating the interlayer insulating film ILD and the buffer layer BF. The first sub-driving power supply line VSLa may be connected to a second sub-driving power supply line VSLb. The first and second sub-driving power supply lines VSLa and VSLb may be connected to each other to form the second driving power supply line VSL. For example, the second driving power supply line VSL may include a first sub-driving power supply line VSLa extending in the first direction D1 and a second sub-driving power supply line VSLb extending in the second direction D2.

A first passivation layer PAS1 may be disposed on the data line DL, the first connection electrode CNE1, the second connection electrode CNE2, the third connection electrode CNE3, the fourth connection electrode CNE4, the fifth connection electrode CNE5, the sixth connection electrode CNE6, the seventh connection electrode CNE7, and the eighth connection electrode CNE8. The first passivation layer PAS1 may include an inorganic film.

A first via layer VA1 may be disposed on the first passivation layer PAS1. The first via layer VA1 may have a first hole HL1 and a second hole HL2. The first and second holes HL1 and HL2 may penetrate the first via layer VA1 in the third direction D3. The first and second holes HL1 and HL2 may overlap the data line DL. For example, in a plan view, the entire first and second holes HL1 and HL2 may overlap the data line DL. The first and second holes HL1 and HL2 may overlap a shielding line SHD. For example, the first hole HL1 may penetrate the first via layer VA1 and be disposed between one side or a side of the data line DL and the shielding line SHD, and the second hole HL2 may penetrate the first via layer VA1 and be disposed between the other side or another side of the data line DL and the shielding line SHD. The first via layer VA1 may include an organic film including an acrylic resin, epoxy resin, phenolic resin, polyamide resin, or polyimide resin.

The shielding line SHD, a shielding electrode SHG, the second sub-driving power supply line VSLb, and an anode connection electrode ACE may be disposed on the first via layer VA1.

The shielding line SHD may be disposed on the first via layer VA1 to overlap the data line DL, the first hole HL1, and the second hole HL2. The shielding line SHD may be disposed in the first and second holes HL1 and HL2 of the first via layer VA1. Direct current (DC) power (for example, a DC voltage) may be applied to the shielding line SHD. To this end, the shielding line SHD may be connected to a power supply line. As the shielding line SHD is disposed to overlap the data line DL, the coupling between the data line DL and the anode electrode AE can be minimized. Consequently, the capacitance between the data line DL and the anode electrode AE can be minimized. Therefore, the voltage of the anode electrode AE can be stably maintained.

The shielding electrode SHG may be disposed on the first via layer VA1 to overlap the first and seventh connection electrodes CNE1 and CNE7. The shielding electrode SHG may be connected to the seventh connection electrode CNE7 through an eighteenth contact hole CT18 penetrating the first via layer VA1 and the first passivation layer PAS1. As the shielding electrode SHG is disposed to overlap the first connection electrode CNE1, the voltage of the first node N1 can be maintained stably.

The second sub-driving power supply line VSLb may be disposed on the first via layer VA1 to overlap the eighth connection electrode CNE8. The second sub-driving power supply line VSLb may be connected to the eighth connection electrode CNE8 through a nineteenth contact hole CT19 penetrating the first via layer VA1 and the first passivation layer PAS1. The second sub-driving power supply line VSLb may be connected to the first sub-driving power supply line VSLa through the eighth connection electrode CNE8. The second sub-driving power supply line VSLb may be connected to an upper connection electrode disposed on a same layer as the anode electrode AE. For example, the upper connection electrode may be connected to the second sub-driving power supply line VSLb through a twenty-first contact hole CT21 penetrating a second via layer VA2 and the second passivation layer PAS2.

The anode connection electrode ACE may be disposed on the first via layer VA1 to overlap the fourth and sixth connection electrodes CNE4 and CNE6. The anode connection electrode ACE may be connected to the sixth connection electrode CNE6 through a twentieth contact hole CT20.

A second passivation layer PAS2 may be disposed on the shielding line SHD, the shielding electrode SHG, the second sub-driving power supply line VSLb, and the anode connection electrode ACE. The second passivation layer PAS2 may include an inorganic film.

The second via layer VA2 may be disposed on the second passivation layer PAS2. The second via layer VA2 may include a same material as the first via layer VA1.

The light-emitting element layer EMTL may be disposed on the second via layer VA2. The light-emitting element layer EMTL may include a pixel-defining film (or pixel-defining layer) PDL and the light-emitting element ED, which may be stacked in the third direction D3. Here, the light-emitting element ED may include the anode electrode AE, the light-emitting layer EL, and a cathode electrode CE.

The anode electrode AE of the light-emitting element ED may be disposed on the second via layer VA2. The anode electrode AE may be connected to the anode connection electrode ACE through a twenty-second contact hole CT22 penetrating the second via layer VA2 and the second passivation layer PAS2. The anode electrode AE may not overlap the first and second holes HL1 and HL2. Reference numerals AE′ and AE″ refer to the anode electrodes of other pixels.

An emission area EA refers to the area where the anode electrode AE, the light-emitting layer EL, and the cathode electrode CE may be sequentially stacked each other, and where holes from the anode electrode AE and electrons from the cathode electrode CE combine in the light-emitting layer EL to emit light.

In a top emission structure, where light is emitted in the direction of the cathode electrode CE relative to the light-emitting layer EL, the anode electrode AE may be formed as a single layer of Mo, titanium (Ti), copper (Cu), or aluminum (Al), or as a stacked structure to increase reflectivity, such as a titanium/aluminum/titanium (Ti/Al/Ti) structure, an aluminum/ITO/aluminum (ITO/Al/ITO) structure, a silver (Ag)-palladium (Pd)-copper (Cu) (APC) alloy, or an APC alloy/ITO structure (for example, ITO/APC/ITO).

The pixel-defining film PDL may define the emission area EA of the pixel PX. To this end, the pixel-defining film PDL may be disposed on the second via layer VA2 to expose a portion of the anode electrode AE. The pixel-defining film PDL may cover the edges of the anode electrode AE. The pixel-defining film PDL may overlap the first and second holes HL1 and HL2. The pixel-defining film PDL may be formed of an organic film such as an acrylic resin, epoxy resin, phenolic resin, polyamide resin, or polyimide resin.

The light-emitting layer EL may be disposed on the anode electrode AE. The light-emitting layer EL may include an organic material that can emit light of a selectable color. For example, the light-emitting layer EL may include a hole transport layer, an organic material layer, and an electron transport layer. The organic material layer may include a host and a dopant. The organic material layer may include a material that emits light of a selectable wavelength and may be formed using a phosphorescent material or a fluorescent material.

For example, the organic material layer of the light-emitting layer EL emitting light of a first color (for example, blue) may include a host material containing carbazole biphenyl (CBP) or 1,3-bis(carbazol-9-yl) (mCP) and a phosphorescent dopant material containing (4,6-F2ppy)2Irpic or L2BD111, but the disclosure is not limited thereto.

The organic material layer of the light-emitting layer EL emitting light of a second color (for example, green) may include a host material containing CBP or mCP and a phosphorescent dopant material containing fac tris(2-phenylpyridine)iridium (Ir(ppy)3). By way of example, the organic material layer of the light-emitting layer EL emitting light of the second color may be a fluorescent material containing tris(8-hydroxyquinolino)aluminum (Alq3), but the disclosure is not limited thereto.

The organic material layer of the light-emitting layer EL emitting light of a third color (for example, red) may include a host material containing CBP or mCP and a phosphorescent dopant material containing bis(1-phenylisoquinoline)acetylacetonate iridium (PIQIr(acac)), bis(1-phenylquinoline)acetylacetonate iridium (PQIr(acac)), tris(1-phenylquinoline)iridium (PQIr), or octaethylporphyrin platinum (PtOEP), but the disclosure is not limited thereto. By way of example, the organic material layer of the light-emitting layer EL emitting light of the third color may be a fluorescent material containing PBD:Eu(DBM)3(Phen) or perylene, but the disclosure is not limited thereto.

The cathode electrode CE may be disposed on the light-emitting layer EL. The cathode electrode CE may be disposed to cover the light-emitting layer EL. The cathode electrode CE may be a common layer commonly disposed on light-emitting layers EL. A capping layer may be formed on the cathode electrode CE.

In a top emission structure, the cathode electrode CE may be formed of a transparent conductive oxide (TCO) such as ITO or indium-zinc-oxide (IZO) that can transmit light, or a semi-transmissive conductive material such as magnesium (Mg), silver (Ag), or an alloy thereof. In case that the cathode electrode CE is formed of a semi-transmissive conductive material, the light output efficiency can be increased by micro cavities.

The encapsulation layer ENC may be formed on the light-emitting element layer EMTL. The encapsulation layer ENC may include at least one inorganic film to prevent oxygen or moisture from penetrating the light-emitting element layer EMTL. The encapsulation layer ENC may include at least one organic film to protect the light-emitting element layer EMTL from foreign substances such as dust. For example, the encapsulation layer ENC may include a first encapsulation inorganic film TFE1, an encapsulation organic film TFE2, and a second encapsulation inorganic film TFE3.

The first encapsulation inorganic film TFE1 may be disposed on the cathode electrode CE, the encapsulation organic film TFE2 may be disposed on the first encapsulation inorganic film TFE1, and the second encapsulation inorganic film TFE3 may be disposed on the encapsulation organic film TFE2. The first and second encapsulation inorganic films TFE1 and TFE3 may be formed as multilayer films in which one or more inorganic films among a silicon nitride film, a silicon oxynitride film, a silicon oxide film, a titanium oxide film, and an aluminum oxide film may be alternately stacked each other. The encapsulation organic film TFE2 may be an organic film including a material such as an acrylic resin, epoxy resin, phenolic resin, polyamide resin, or polyimide resin.

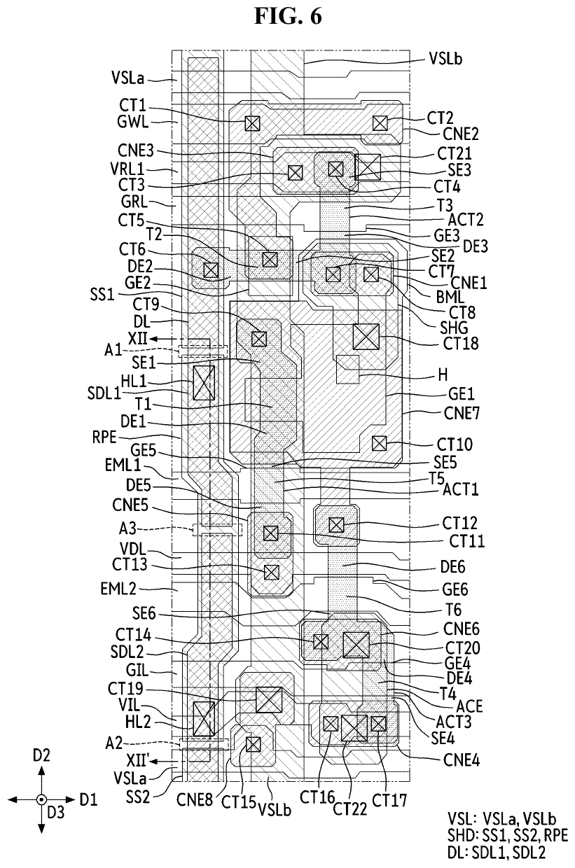

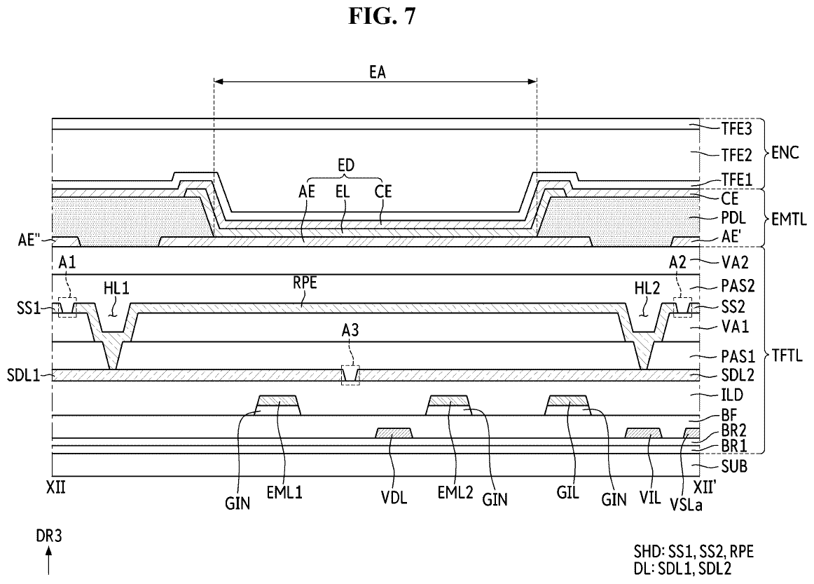

FIG. 6 is a diagram illustrating the array of a display device 100 according to an embodiment, and FIG. 7 is a schematic cross-sectional view taken along line XII-XII′ of FIG. 6.

The display device 100 of FIGS. 6 and 7 may differ from the display device 100 of FIGS. 4 and 5 in the shape of a data line DL and a shielding line SHD, and will hereinafter be described, focusing on this difference.

Referring to FIGS. 6 and 7, the shielding line SHD may be cut in a first region A1 and a second region A2, and the data line DL may be cut in a third region A3. In a plan view, the third region A3 may be disposed between the first and second regions A1 and A2.

As the shielding line SHD is cut in the first and second regions A1 and A2, the shielding line SHD may include a first sub-shielding line SS1, a second sub-shielding line SS2, and a repair electrode RPE, which are separated from one another. The repair electrode RPE may be disposed between the first and second sub-shielding lines SS1 and SS2.

As the data line DL is cut in the third region A3, the data line DL may include a first sub-data line SDL1 and a second sub-data line SDL2, which are separated from each other. In a plan view, the facing ends of the first and second sub-data lines SDL1 and SDL2 may be disposed between a first hole HL1 and a second hole HL2.

The repair electrode RPE may overlap the facing ends of the first and second sub-data lines SDL1 and SDL2. For example, the repair electrode RPE may overlap one end of the first sub-data line SDL1 in the third region A3 and one end of the second sub-data line SDL2 in the third region A3.

In a plan view, the first hole HL1 may be disposed between one end of the repair electrode RPE facing the first sub-shielding line SS1 and one end of the first sub-data line SDL1 facing the second sub-data line SDL2. In other words, in a plan view, the first hole HL1 may be disposed between one end of the repair electrode RPE in the first region A1 and one end of the first sub-data line SDL1 in the third region A3.

In a plan view, the second hole HL2 may be disposed between the other end of the repair electrode RPE facing the second sub-shielding line SS2 and one end of the second sub-data line SDL2 facing the first sub-data line SDL1. In other words, in a plan view, the second hole HL2 may be disposed between the other end of the repair electrode RPE in the second region A2 and one end of the second sub-data line SDL2 in the third region A3.

Each of the first and second holes HL1 and HL2 may further penetrate the first passivation layer PAS1. In other words, the first hole HL1 may penetrate both the first via layer VA1 and the first passivation layer PAS1, and the second hole HL2 may penetrate both the first via layer VA1 and the first passivation layer PAS1.

One side or a side of the repair electrode RPE may be connected to the first sub-data line SDL1, and the other side or another side of the repair electrode RPE may be connected to the second sub-data line SDL2. For example, one side or a side of the repair electrode RPE may be connected to the first sub-data line SDL1 through the first hole HL1, and the other side or another side of the repair electrode RPE may be connected to the second sub-data line SDL2 through the second hole HL2. Accordingly, the cut data line DL may be repaired through the repair electrode RPE. In other words, the first sub-data line SDL1 disposed on one side or a side of the third region A3 and the second sub-data line SDL2 disposed on the other side or another side of the third region A3 may be connected to each other through the repair electrode RPE.

DC power may be properly supplied to the cut shielding line SHD. In other words, a data voltage DATA from the data line DL may be applied to the portion of the cut shielding line SHD used as the repair electrode RPE, while DC power may be supplied to the rest of the cut shielding line SHD (for example, the first and second sub-shielding lines SS1 and SS2).

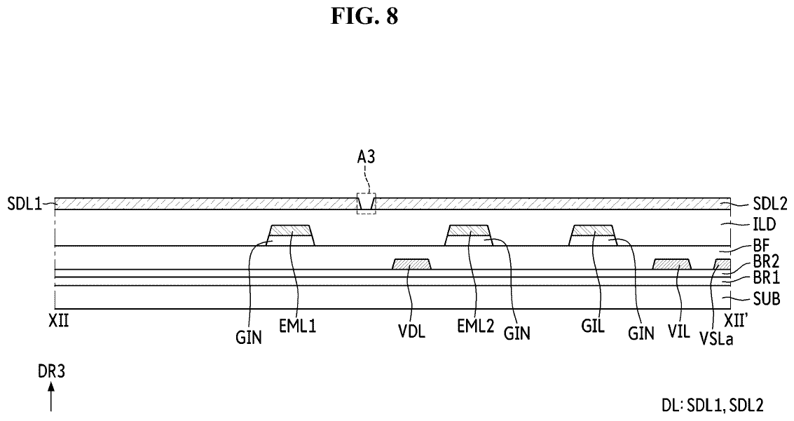

FIGS. 8 through 13 are schematic cross-sectional views for explaining a method of manufacturing a display device 100 according to an embodiment. For example, FIGS. 8 through 13 may be schematic cross-sectional views for explaining a repair method for an open-circuited data line DL.

First, referring to FIG. 8, a data line DL may be formed on a substrate SUB. For example, the data line DL may be disposed on an interlayer insulating film ILD. During the formation of the data line DL, a line defect such as an open circuit may occur in the data line DL. For example, as the data line DL is cut in a third region A3, the data line DL may be divided into a first sub-data line SDL1 and a second sub-data line SDL2.

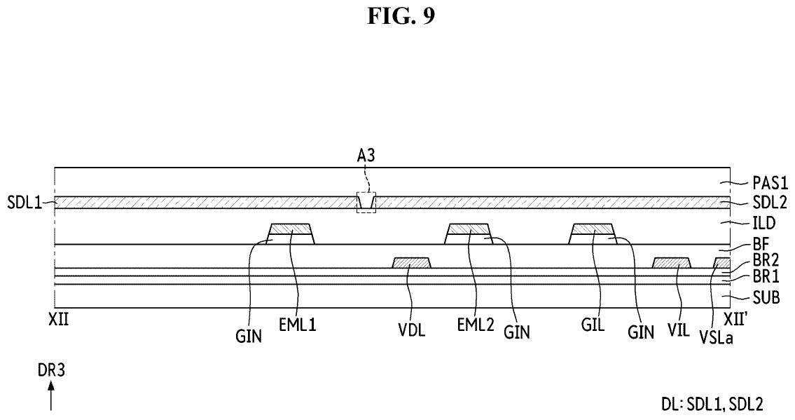

Thereafter, referring FIG. 9, a first passivation layer PAS1 may be formed on the data line DL.

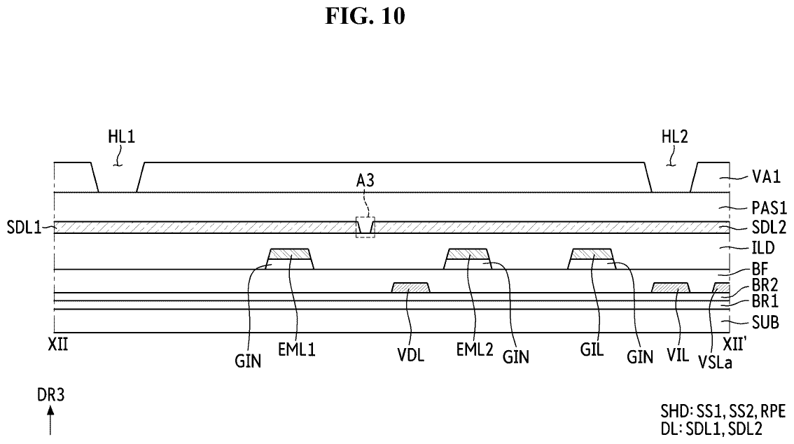

Thereafter, referring to FIG. 10, a first via layer VA1 with first and second holes HL1 and HL2 may be formed on the first passivation layer PAS1.

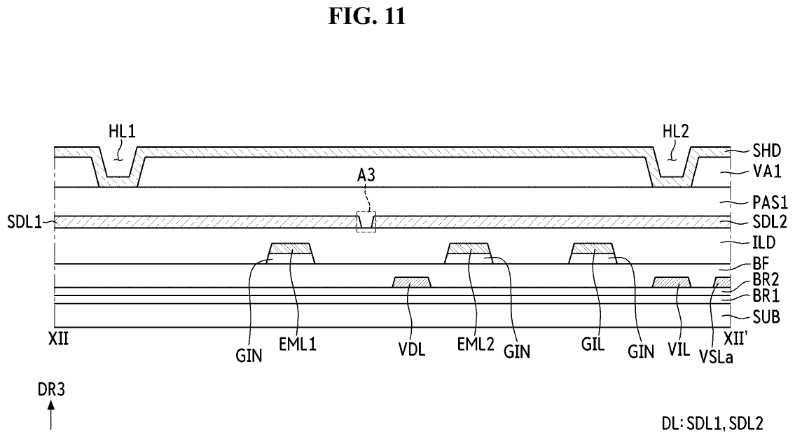

Thereafter, referring to FIG. 11, a shielding line SHD may be formed on the first via layer VA1.

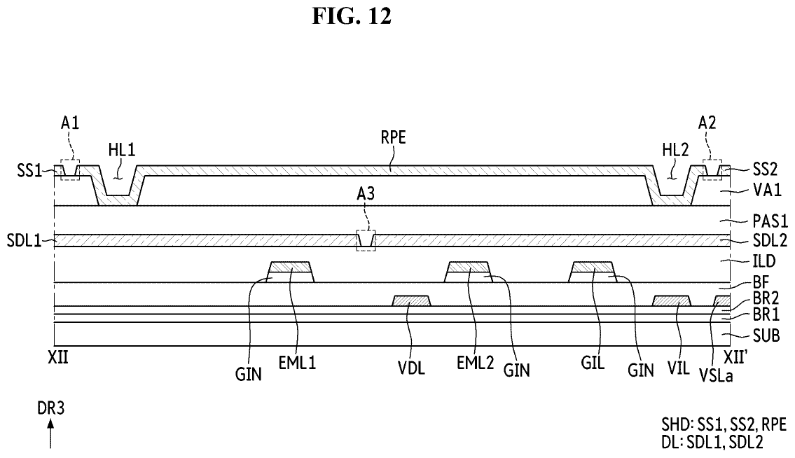

Thereafter, referring to FIG. 12, laser beams may be irradiated onto first and second regions A1 and A2 on the shielding line SHD, thereby cutting the shielding line SHD in the first and second regions A1 and A2. Accordingly, a repair electrode RPE may be formed in the region overlapping the region (for example, the third region A3) where the data line DL is cut, a first sub-shielding line SS1 may be formed on one side or a side of the repair electrode RPE, and a second sub-shielding line SS2 may be formed on the other side or another side of the repair electrode RPE.

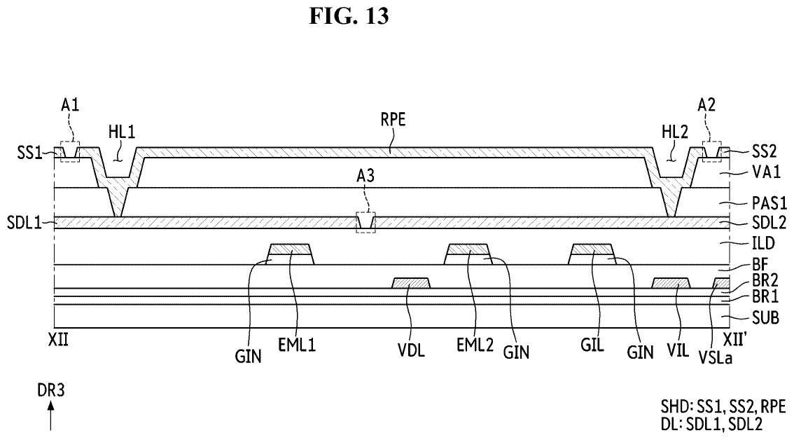

Thereafter, referring to FIG. 13, laser beams may be irradiated toward the first and second holes HL1 and HL2. Accordingly, the first passivation layer PAS1 may be removed in the regions corresponding to the first hole HL1 and the second hole HL2, thereby exposing the data line DL. In other words, by irradiating the laser beams, the depths of the first and second holes HL1 and HL2 may be increased, thereby allowing the first hole HL1 to penetrate the first via layer VA1 and the first passivation layer PAS1, and the second hole HL2 to penetrate the first via layer VA1 and the first passivation layer PAS1. The repair electrode RPE in the first and second holes HL1 and may be connected to the data line DL by the irradiation of the laser beams. For example, one side or a side of the repair electrode RPE may be connected to the first sub-data line SDL1 through the first hole HL1, and the other side or another side of the repair electrode RPE may be connected to the second sub-data line SDL2 through the second hole HL2.

The display device 100 according to the embodiment can be applied to various electronic devices. The electronic device according to an embodiment may include the display device 100 described above and may further include modules or devices having additional functions in addition to the display device 100.

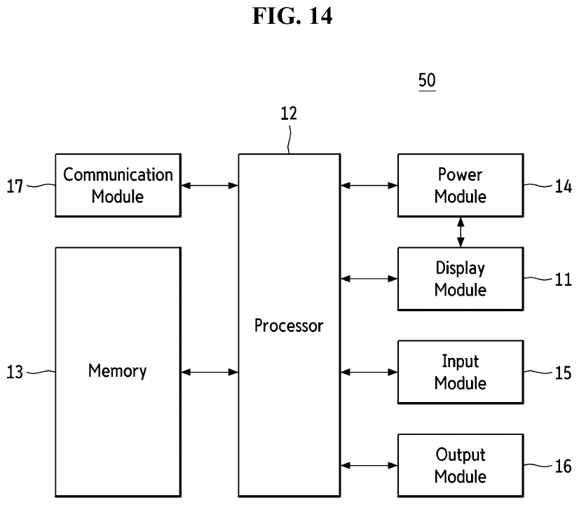

FIG. 14 is a block diagram of an electronic device according to an embodiment. Referring to FIG. 14, the electronic device 50 according to an embodiment may include a display module 11, a processor 12, a memory 13, and a power module 14. The electronic device 5000 may further include an input module 14, a non-image output module 15 and/or a communication module 16.

The electronic device 50 may output various information in the form of images through the display module 11. In case that the processor 12 executes an application stored in the memory 13, image information provided by the application may be provided to the user through the display module 1100. The power module 14 may include a power supply module such as a power adapter or a battery device, and a power conversion module that converts the power supplied by the power supply module to generate power required for the operation of the electronic device 5000. The input module 14 may provide input information to the processor 12 and/or the display module 11. The non-image output module 15 may receive information other than images transmitted from the processor 12, such as sound, haptics, and light, and provide the information to the user. The communication module 16 may be a module that is responsible for transmitting and receiving information between the electronic device 5000 and an external device, and may include a receiving unit and a transmitting unit.

At least one of the components of the electronic device 50 described above may be included in the display device 100 according to the embodiments described above. In addition, some of the individual modules functionally included in one module may be included in the display device 100, and others may be provided separately from the display device 100. For example, the display device 100 may include a display module 11, and the processor 12, memory 13, and power module 14 may be provided in the form of other devices within the electronic device 11 other than the display device 100.

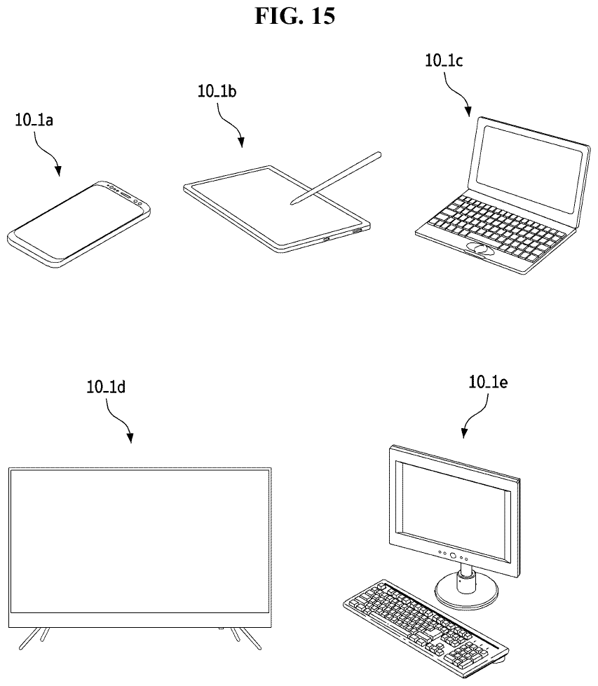

FIGS. 15, 16, and 17 are schematic diagrams of electronic devices according to various embodiments. FIGS. 15 to 17 illustrate examples of various electronic devices to which the display device 100 according to the embodiments is applied.

FIG. 15 illustrates a smartphone 10_1a, a tablet PC 10_1b, a laptop 10_1c, a TV 10_1d, and a desk monitor 10_1e as examples of electronic devices.

In addition to the display module 11, the smartphone 10_1a may include an input module such as a touch sensor and a communication module. The smartphone 10_1a may process information received through the communication module or other input modules and display the information through the display module of the display device 100.

In the case of tablet PCs 10_1b, laptops 10_1c, TVs 10_1d, and desk monitors 10_1e, they may include display modules and input modules similar to smartphones 10_1, and may additionally include communication modules in some cases.

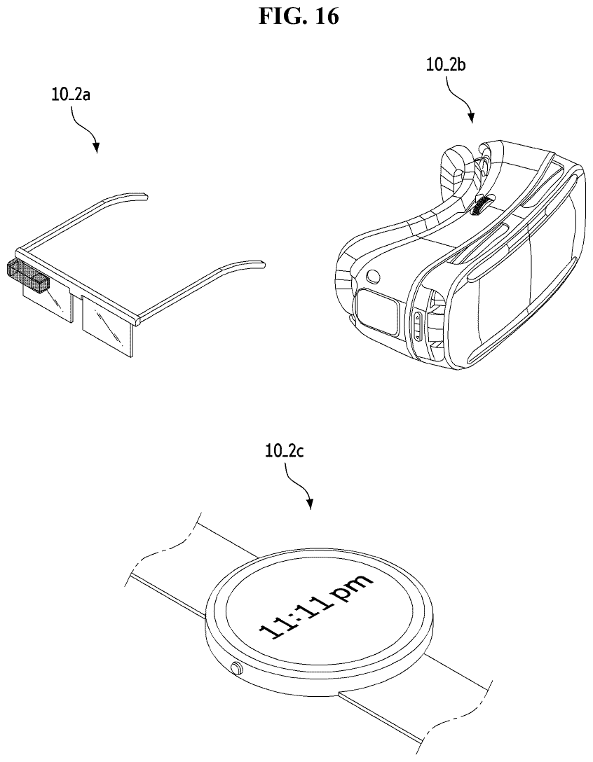

FIG. 16 shows an example of an electronic device including a display module being applied to a wearable electronic device. The wearable electronic device may be a smart glasses 10_2a, a head-mounted display 10_2b, a smart watch 10_2c, etc.

The smart glasses 10_2a and the head-mounted display 10_2b may include a display module that emits a display image and a reflector that reflects the emitted display screen and provides it to the user's eyes, thereby providing a virtual reality or augmented reality screen to the user.

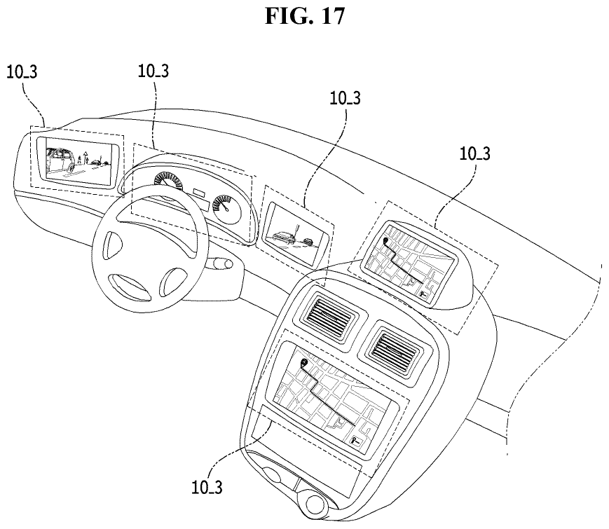

The smart watch 10_2c may include a biometric sensor as an input device, and may provide biometric information recognized by the biometric sensor to the user through the display module. FIG. 17 illustrates a case where an electronic device including a display module is applied to a vehicle. For example, the electronic device 10_3 may be applied to a dashboard, center fascia, etc. of a vehicle, or may be applied to a CID (Center Information Display) placed on a dashboard of a vehicle, or a room mirror display replacing a side mirror.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure and as set forth in the following claims.

What is claimed is:

1. A display device comprising:
a data line disposed on a substrate;
a passivation layer disposed on the data line;
a via layer disposed on the passivation layer;
a shielding line disposed on the via layer and overlapping the data line;
a light-emitting element layer disposed on the shielding line;
a first hole penetrating the via layer and overlapping a side of the data line; and
a second hole penetrating the via layer and overlapping another side of the data line.

2. The display device of claim 1, wherein the shielding line receives a direct current (DC) power.

3. The display device of claim 1, wherein the shielding line is disposed in the first hole and the second hole.

4. The display device of claim 1, wherein
the light-emitting element layer comprises an anode electrode and a pixel-defining layer disposed on the anode electrode, and
the first hole and the second hole do not overlap the anode electrode.

5. The display device of claim 4, wherein the first hole and the second hole overlap the pixel-defining layer.

6. The display device of claim 1, wherein
the data line includes a first sub-data line and a second sub-data line separated from each other, and
facing ends of the first sub-data line and the second sub-data line are disposed between the first hole and the second hole in a plan view.

7. The display device of claim 6, wherein the shielding line includes a repair electrode, a first sub-shielding line, and a second sub-shielding line that are separated from each other.

8. The display device of claim 7, wherein the repair electrode overlaps facing ends of the first sub-data line and the second sub-data line.

9. The display device of claim 8, wherein
the first hole is disposed between an end of the repair electrode facing the first sub-shielding line and an end of the first sub-data line facing the second sub-data line in a plan view, and
the second hole is disposed between another end of the repair electrode facing the second sub-shielding line and an end of the second sub-data line facing the first sub-data line in a plan view.

10. The display device of claim 9, wherein each of the first hole and the second hole further penetrates the passivation layer.

11. The display device of claim 10, wherein
a side of the repair electrode is connected to the first sub-data line through the first hole, and
another side of the repair electrode is connected to the second sub-data line through the second hole.

12. The display device of claim 11, wherein
the repair electrode receives a data voltage from the data line, and
each of the first sub-shielding line and the second sub-shielding line receives a DC power.

13. A display device comprising:
a data line disposed on a substrate;
a passivation layer disposed on the data line;
a via layer disposed on the passivation layer;
a shielding line disposed on the via layer and overlapping the data line;
a light-emitting element layer disposed on the shielding line;
a first hole penetrating the via layer and disposed between a side of the data line and the shielding line; and
a second hole penetrating the via layer and disposed between another side of the data line and the shielding line.

14. The display device of claim 13, wherein the shielding line receives a direct current (DC) power.

15. The display device of claim 13, wherein the shielding line is disposed in the first hole and the second hole.

16. The display device of claim 13, wherein
the light-emitting element layer includes an anode electrode and a pixel-defining layer disposed on the anode electrode, and
the first hole and the second hole do not overlap the anode electrode.

17. The display device of claim 16, wherein the first hole and the second hole overlap the pixel-defining layer.

18. The display device of claim 13, wherein
the data line includes a first sub-data line and a second sub-data line that are separated from each other, and
facing ends of the first sub-data line and the second sub-data line are disposed between the first hole and the second hole in a plan view.

19. The display device of claim 18, wherein the shielding line includes a repair electrode, a first sub-shielding line, and a second sub-shielding line that are separated from one another.

20. The display device of claim 19, wherein the repair electrode overlaps facing ends of the first sub-data line and the second sub-data line.

21. The display device of claim 20, wherein
the first hole is disposed between an end of the repair electrode facing the first sub-shielding line and an end of the first sub-data line facing the second sub-data line in a plan view, and
the second hole is disposed between another end of the repair electrode facing the second sub-shielding line and an end of the second sub-data line facing the first sub-data line in a plan view.

22. The display device of claim 21, wherein each of the first hole and the second hole further penetrates the passivation layer.

23. The display device of claim 22, wherein
a side of the repair electrode is connected to the first sub-data line through the first hole, and
another side of the repair electrode is connected to the second sub-data line through the second hole.

24. The display device of claim 23, wherein
the repair electrode receives a data voltage from the data line, and
each of the first sub-shielding line and the second sub-shielding line receives a DC power.

25. An electronic device comprising:
a display device including a screen;
wherein the display device comprises:
a data line disposed on a substrate;
a passivation layer disposed on the data line;
a via layer disposed on the passivation layer;
a shielding line disposed on the via layer and overlapping the data line;
a light-emitting element layer disposed on the shielding line;
a first hole penetrating the via layer and overlapping a side of the data line; and
a second hole penetrating the via layer and overlapping another side of the data line.
